(19) United States
(12) Patent Application Publication
(10) Pub. No.: US 2007/0096083 A1
(43) Pub. Date: May 3, 2007

(54) Substrate core polymer nanocomposite with nanoparticles and randomly oriented nanotubes and method

(75) Inventors: Nachiket Raravikar, Chandler, AZ (US); Ravindra V. Tanikella, Phoenix, AZ (US); Nirupama Chakrapani, Chandler, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/259,806

(22) Filed: Oct. 27, 2005

(51) Int. Cl. H01L 51/00

(52) U.S. Cl. 257/40; 977/700; 257/E51.02

(57) ABSTRACT

Embodiments of substrate core polymer nanocomposite with nanoparticles and randomly oriented nanotubes and method for making the substrate core are generally described herein. Other embodiments may be described and claimed. In some embodiments, a nanotube suspension is combined with nanoparticle-impregnated polymer.

### TECHNICAL FIELD

Some embodiments of the present invention pertain to microelectronic substrates including multilayer substrates. Some embodiments of the present invention pertain to substrate cores and methods for making substrates and substrate cores.

### BACKGROUND

It is desirable for microelectronic substrates to exhibit high-stiffness, a low coefficient of thermal expansion (CTE), good adhesion with via-metals, flame retardancy, high thermal conductivity, and good machinability. Conventional microelectronic substrates have to make tradeoffs between these various characteristics.

Conventionally, increased stiffness and lower CTE have been achieved by increasing the amount of ceramic or glass fiber added to the substrate core material. This has a detrimental effect on the reliability of the substrates as well as the manufacturability of the substrate core with respect to drilling the vias for plated through holes (PTHs).

### BRIEF DESCRIPTION OF THE DRAWINGS

FIG. 1 illustrates a cross section of a semiconductor substrate in accordance with some embodiments of the present invention; and

FIG. 2 is a flow chart of a procedure for making a polymer nanocomposite substrate core in accordance with some embodiments of the present invention.

### DETAILED DESCRIPTION

The following description and the drawings illustrate specific embodiments of the invention sufficiently to enable those skilled in the art to practice them. Other embodiments may incorporate structural, logical, electrical, process, and other changes. Examples merely typify possible variations. Individual components and functions are optional unless explicitly required, and the sequence of operations may vary. Portions and features of some embodiments may be included in or substituted for those of others. Embodiments of the invention set forth in the claims encompass all available equivalents of those claims. Embodiments of the invention may be referred to herein, individually or collectively, by the term “invention” merely for convenience and without intending to limit the scope of this application to any single invention or inventive concept if more than one is in fact disclosed.

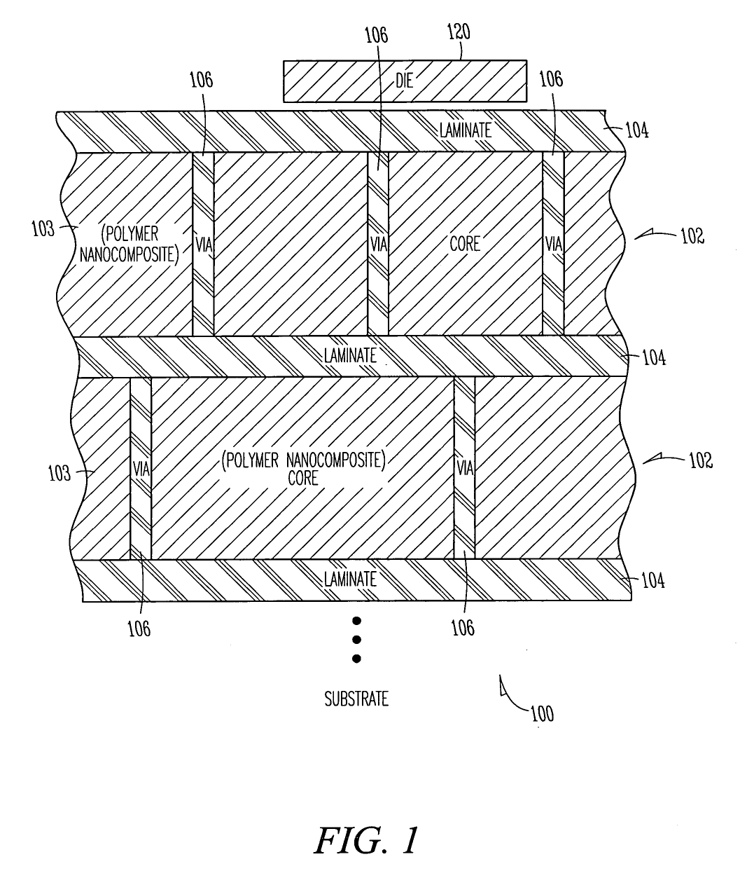

FIG. 1 illustrates a cross section of a semiconductor substrate in accordance with some embodiments of the present invention. Semiconductor substrate 100 comprises one or more core layers 102 sandwiched between two or more laminate layers 104. Core layers 102 may include vias 106. In accordance with some embodiments of the present invention, each of core layers 102 may comprise polymer nanocomposite 103 that may be made by combining a nanotube suspension with a nanoparticle-impregnated polymer. The process of making the polymer material for core layer 102 is discussed in more detail below.

Laminate layers 104 may comprise conductive, dielectric and/or insulating layers, such as glass-reinforced epoxy, cyanate ester, bismaelimide or polyimide based composites. Alternatively ceramic or metallic (e.g., conductive) substrate cores may be used. These substrates may be used as chip carriers, interposers between die to package or package to mother board, as printed circuit boards (mother boards), or as other signal or power redistribution applications in semiconductor packaging and enabling technologies. In some embodiments, laminate layers 104 may comprise of copper cladding formed by processes such as lamination or using a vacuum press. For example, substrate 100 may couple with one or more semiconductor die 120 and may be part of a processing system, although the scope of the invention is not limited in this respect.

In some embodiments, the nanoparticle-impregnated polymer may comprise nanoparticles having a diameter of approximately less than 100 nanometers. In some embodiments, the nanoparticles may comprise an oxide powder. In some embodiments, the nanoparticles may comprise either fractured alumina or fractured silica, although the scope of the invention is not limited in this respect. In some embodiments, the diameter of the nanoparticles may range from about 10 to 15 nanometers to about 50 to 100 nanometers, while in other embodiments the diameter of the nanoparticles may range between 20 and 40 nanometers, although the scope of the invention is not limited in this respect.

In some embodiments, the nanotubes of the nanotube suspension may comprise electrically insulating nanotubes to provide an electrically insulating polymer composite for core layer 102. In these embodiments, boron-nitride nanotubes may be used, although the scope of the invention is not limited in this respect.

In some embodiments, the nanotubes of the nanotube suspension may comprise electrically conductive nanotubes to provide an electrically conductive polymer composite for core layer 102. In these embodiments, either carbon nanotubes or carbon nanofibers may be used, although the scope of the invention is not limited in this respect. In some embodiments, the nanotubes may be concentric shells of graphite formed by one sheet of conventional graphite rolled up into a cylinder. The lattice of carbon atoms remains continuous around the circumference. In some embodiments, the tiny, hollow nanotubes may be made of pure carbon and may be few nanometers in diameter. In some embodiments, the nanotubes may be individual single-wall structures that may have the electrical conductivity of copper or silicon, the thermal conductivity of diamond, and may be stiffer and stronger that many conventional fibers. In some embodiments, nanotubes may be carbon nanotubes comprising cylindrical carbon molecules, although the scope of the invention is not limited in this respect.

In some embodiments, the nanotube suspension may be generated by functionalizing nanotubes with molecules of either an acid or an amino group. Generating the nanotube suspension may also include sonicating the nanotubes as part of functionalizing the nanotubes. In these embodiments, ultrasonic energy may be used to help separate and disperse the nanotubes from bundles. In some embodiments, when sonicating is combined with functionalization in an acid reflux, functionalization of the nanotubes may be accomplished quicker.

In some embodiments, functionalizing comprises attaching molecules of either the acid or the amino group to surfaces of the nanotubes. In some embodiments, an acid reflux may be used to functionalize the nanotubes. In some embodiments, the molecules of the acid group may include —CCOH or —OH, and the molecules of the amino group may include —CONH or —NH2, although the scope of the invention is not limited in this respect.

In some embodiments, the nanotubes may be characterized for functionalities by detecting the attachment or presence of molecules of either the acid or the amino group on the surfaces of the nanotubes. In some embodiments, characterizing may include using either infrared spectrography or an electron microscope. Alternatively, characterization may include forms of Raman spectroscopy and Atomic Force Microscopy. In some embodiments, the characterization may be optional.

In some alternative embodiments, instead of nanotubes, nanofibers may be used. In these embodiments, the suspension may be referred to as a nanofiber suspension. In these embodiments, the nanofiber suspension is mixed with the nanoparticle-impregnated polymer. In these embodiments, the nanofiber suspension may be generated by functionalizing the nanofibers with molecules of either an acid or an amino group, and characterizing the nanofibers for functionalities as discussed above.

In some embodiments, combining the nanotube suspension with the nanoparticle-impregnated polymer provides a polymer composite. The polymer composite may be cured in a mold. In some embodiments, the mold may have substantially cylindrical protrusions therein to form vias 106 in nanocomposite substrate core 102, although the scope of the invention is not limited in this respect. In these embodiments, vias 106 may be holes that correspond to plated-through-holes (PTHs) in substrate 100. In the case of non-conducting substrates, vias may be plated, although the scope of the invention is not limited in this respect. In some embodiments, nanocomposite substrate core 102 may comprise either a conductive or a non-conductive substrates core with via-in-via configurations allowing isolation of electrical conducting paths as needed by the use of insulating materials such as filled epoxies, although the scope of the invention is not limited in this respect.

In some embodiments, the nanoparticle-impregnated polymer may be generated by combining either an epoxy resin or a thermoplastic polymer with an oxide powder of the nanoparticles. In some embodiments, a small concentration loading (e.g., approximately 0.5 to 1.0 percent weight) of nanoparticles may be mixed with the polymer. In some embodiments, the nanoparticles may be untreated, while in other embodiments (e.g., using epoxy resin and/or using greater concentration loadings), the nanoparticles may be treated and may comprise silane treated silica-nanoparticles, although the scope of the invention is not limited in this respect.

In some embodiments, the nanoparticle-impregnated polymer may be generated by combining either an uncured epoxy resin or a thermoplastic polymer with the nanoparticles and may include sonicating (i.e., providing ultrasonic energy) the mixture.

The nanoparticles may be purchased commercially or may be fabricated with a physical vapor deposition process or a sol-gel synthesis process, although the scope of the invention is not limited in this respect. In some embodiments, the epoxy resin may be thermally curable or curable by ultraviolet, although the scope of the invention is not limited in this respect. In some embodiments, the thermoplastic polymer may include Polymethyl methacrylate (PMMA), Polystyrene (PS) or Polycarbonate (PC), although other thermoplastic polymers may be used.

In some embodiments, the nanotube suspension may be combined with the nanoparticle-impregnated polymer using a melt-mixing process discussed in more detail below. In some alternative embodiments, the nanotube suspension may be combined with the nanoparticle-impregnated polymer using a solvent-mixing process discussed in more detail below. In the embodiments that use the solvent-mixing process, the nanotube suspension may be mixed with a selected solvent, and the nanoparticle-impregnated polymer may include an uncured epoxy, epoxy resin, or a thermoplastic polymer mixed with the selected solvent. The selected solvent may include an amine based solvent such as tetrahydrafuran or dimethylformamine (DMF). Alternatively, the solvent may include non-amine based solvents, such as dichloromethane, toluene, or acetone, although the scope of the invention is not limited in this respect.

In accordance with some embodiments of the present invention, because the nanotubes have high modulus (˜1 TPa), polymer surfaces may be stiffened by the embedded nanotubes. In some embodiments, the adhesion of nanocomposites with external surfaces may be improved with the addition of nanoparticles as fillers. Since the bulk thermal conductivity of these nanomaterials (e.g., boron nitride or carbon nanotubes) is high, the resulting composite may also have a higher thermal conductivity than what could be achieved using conventional glass fibers. In accordance with some embodiments, the nanoparticles may improve the thermal stability, and hence, improved flame retardancy of the resultant polymer composite may be achieved. In some embodiments, the addition of the nanoparticles and the nanotube into a polymer may also reduce the CTE of the polymer. In accordance with some embodiments, existing assembly techniques may be scaled up to make substrate-core composite materials based on nanotubes and nanoparticles in the polymer matrix as described herein.

In accordance with some embodiments of the present invention, core layer 102 may provide high stiffness, low CTE (e.g., low warpage), improved adhesion with via metals (e.g., copper), improved flame retardancy, and high thermal conductivity. Furthermore, core layer 102 may provide good machinability for drilling the vias for the PTHs. In some embodiments, a significant improvement in these properties may be achieved at lower nano-filler contents than some conventional core fabrication techniques. In some embodiments, drilling the vias may be virtually eliminated through the use of pre-patterned cylinders introduced in the mold. In the embodiments, the cylinders may have a diameter similar to that of a PTH, although the scope of the invention is not limited in this respect.

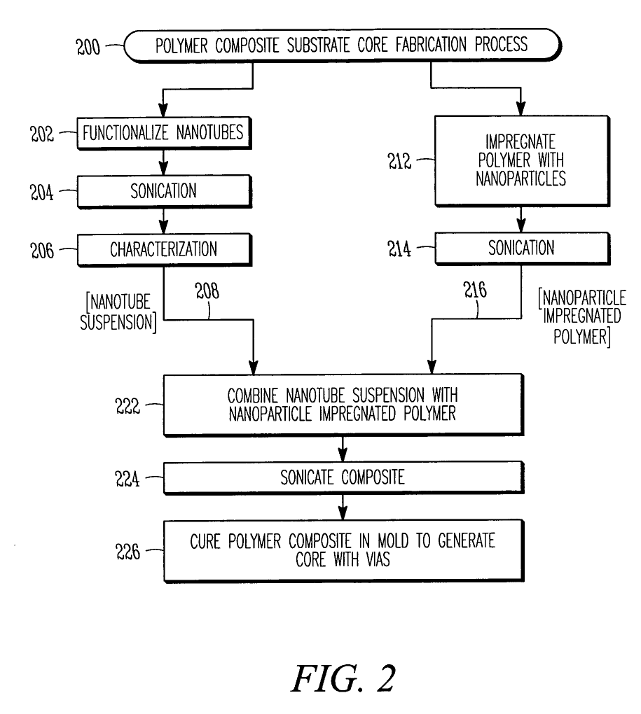

FIG. 2 is a flow chart of a procedure for making a polymer nanocomposite substrate core in accordance with some embodiments of the present invention. Procedure 200 may be used to fabricate a polymer nanocomposite substrate core suitable for use as core layer 102 (FIG. 1), although other fabrication processes may be used. Operations 202 through 206 may be performed to generate nanotube suspension 208 and operations 212 and 214 may be performed to generate nanoparticle impregnated polymer 216. Nanotube suspension 208 and nanoparticle impregnated polymer 216 may be combined and mixed in operations 222 and 224 and may be cured in operation 226 to generate the resultant substrate core. These operations are discussed in more detail below. Although some of the operations are described as using nanotubes, embodiments of the present invention are also applicable to the use nanofibers as an alternative.

Operation 202 comprises functionalizing the nanotubes. In some embodiments, an acid reflux may be used. During functionalizing, molecules may attach to the surfaces of the nanotubes. Functionalized molecules may interact strongly with the matrix polymer in operation 222 and may improve nanotube-polymer interactions and making the composite stronger.

Operation 204 comprises sonicating the nanotubes. In some embodiments, ultrasonic energy may be provided using an ultrasonic bath or ultrasonic probe, which may be immersed into the nanotube suspension. The ultrasonic energy separates the nanotubes from bundles dispersing the nanotubes in a more random orientation. Sonication, combined with acid reflux, may help speed up the nanotube functionalization process, although the scope of the invention is not limited in this respect.

Nanotubes, without any external energy such as sonication, have a tendency to remain in bundles due to their high surface energy. Sonication may help break these nanotube bundles and may separate each nanotube from the others. The separated nanotubes are stronger as mechanical reinforcement in the resultant composites compared to the bundled nanotubes. In some embodiments, the nanotubes may be ultrasonicated in a nitric acid and sulfuric acid bath at room temperature for up to four hours, although the scope of the invention is not limited in this respect.

Operation 206 comprises characterizing the nanotubes for functionalities on their surface. Operation 206 may determine whether the molecules from operation 204 are attached to the surface of the nanotubes. In some embodiments, operation 206 may characterize the nanotubes for functionalities on their surface, such as acid or amino groups. If operation 206 determines that there is insufficient attachment of the molecules, operation 202 and/or 204 may be repeated.

Operation 212 comprises impregnating a polymer with nanoparticles. In some embodiments, a small loading of nanoparticles may be mixed with an uncured epoxy resin by a solution mixing or a melt-mixing process. In some embodiments, the small loading may be approximately 0.5 to 1 percent weight of alumina or silica nanoparticles having a diameter of around 30 nanometers, although the scope of the invention is not limited in this respect. The nanoparticles may be untreated for lower loadings because dispersion issues may not be significant. In some embodiments that use lower loadings, similar composite properties may be achieved while at the same time avoiding modification of the surfaces of the nanoparticle that may be done for higher loadings. In some embodiments, sonication, per operation 214, may be used to help mix the nanoparticles with the uncured epoxy resin or the thermoplastic as part of operation 212.

In some embodiments, silane-treated nanoparticles can be used for mixing with an epoxy to help improve the dispersion of nanoparticles in an epoxy resin, although the scope of the invention is not limited in this respect. In these embodiments, operation 212 may include treating the nanoparticles with functional groups (e.g., silane) so that they may be more easily mixed into a polymer. The silane treatment may help improve the dispersion of the nanoparticles in the polymer matrix subsequently in operation 222. In some alternative embodiments, the polymer used in operation 212 may comprise a thermoplastic polymer, although the scope of the invention is not limited in this respect.

In some embodiments, operation 222 comprises melt mixing. Melt mixing may generate a nanoparticle suspension (or dispersion) in molten epoxy. Melt mixing may be used with either epoxy resin or a thermoplastic polymer. In these embodiments, when melt mixing is used in operation 222, a shear-mixer may apply a shear force to a polymer melt using rotating blades causing good mixing of fillers into the polymer matrix. Subsequently, the melt mixed composite may be poured or drawn into a desired shape.

In some alternative embodiments, operation 222 comprises solvent mixing. In these embodiments, the nanotube suspension generated in operations 202-206 and the uncured epoxy resin from operation 212 may be mixed with a suitable solvent. The two solutions should be made in the same solvent. If an epoxy solution is used, it should be made in the same solvent that is used to make the nanotube suspension. If molten uncured epoxy is used, then the nanotube suspension should be prepared in a solvent in which the uncured epoxy is soluble.

Operation 224 comprises sonicating the polymer composite. In some embodiments, operation 224 may be part of the combining and mixing operations of operation 222.

Operation 226 comprises curing the polymer composite in a mold to generate the core. In some embodiments, the core may be generated in the mold with vias, although the scope of the invention is not limited in this respect. In some solvent mixing embodiments, the composite may be laid over the mold and the solvent may evaporate as the epoxy cures. In some melt-mixing embodiments, the composite may be laid over the mold and the epoxy may be cured. Solvent evaporation is eliminated in the melt-mixing embodiments.

In some embodiments, the mold may be patterned with the cylinders for making vias. The cylinders may be approximately 300 microns (μm) in diameter with a spacing (or pitch) of between 400-600 μm, although the scope of the invention is not limited in this respect. The resulting composite may be viewed as a “mat” having holes of the same diameter as the cylinders. These holes may be used for vias 106 (FIG. 1). This may eliminate any post-curing drilling. In some embodiments, the substrates may then be plated continuously for non-conducting substrates or with via-in-via isolation for conducting substrates, although the scope of the invention is not limited in this respect.

In some embodiments, the polymer composite may be cured at a predetermined temperature for predetermine time, and in some cases, within an inert atmosphere (e.g., nitrogen or argon) to avoid oxidation. In some embodiments, the epoxy may be cured at an elevated temperature, such as 150 degrees Celsius for approximately two hours, although the scope of the invention is not limited in this respect. In some embodiments, a curing agent may be used to harden the polymer composite. In some embodiments in which epoxy resin is used, heat or ultraviolet radiation may be used to cure the composite, although the scope of the invention is not limited in this respect.

After curing and removal from the mold, the core layer may be completed. In some embodiments, a mold-release agent may be used to release the core from the mold. To fabricate a substrate, one or more layers of the core may be sandwiched between various laminates or die-electric layers for integration into a substrate, such as substrate 100 (FIG. 1).

In some embodiments, the mechanical properties of the polymer nanocomposite of core layer 102 (FIG. 1) may be relatively less anisotropic because the fibers may be randomly oriented (e.g., not aligned in any regular fashion and not in bundles). In some embodiments, the nanoparticles may improve the modulus and toughness of the polymer. Due to surface functionalization (discussed above), the interface between the epoxy and the nanotubes is improved along with the nanotube dispersion in the polymer matrix. The interface between the nanoparticles, especially silane-coated nanoparticles, and the polymer may also be improved. The large surface area provided by the nanotubes and the nanoparticles when combined with a good matrix-filler interface may also help improve the mechanical properties as well as the thermal conductivity and thermal stability of the composite at lower filler loadings. In some embodiments, the polymer nanocomposite of core layer 102 (FIG. 1) may reduce core-plug resin CTE mismatch due to the inherently low CTE of nanoparticles and nanotubes.

Although the individual operations of procedure 200 are illustrated and described as separate operations, one or more of the individual operations may be performed concurrently, and nothing requires that the operations be performed in the order illustrated. In particular, operations 202 through 206 may be performed concurrently with operations 212 and 214.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims.

In the foregoing detailed description, various features are occasionally grouped together in a single embodiment for the purpose of streamlining the disclosure. This method of disclosure is not to be interpreted as reflecting an intention that the claimed embodiments of the subject matter require more features than are expressly recited in each claim. Rather, as the following claims reflect, invention may lie in less than all features of a single disclosed embodiment. Thus the following claims are hereby incorporated into the detailed description, with each claim standing on its own as a separate preferred embodiment.

What is claimed is:

1. A method of making a polymer nanocomposite substrate core comprising combining a nanotube suspension with nanoparticle-impregnated polymer.

2. The method of claim 1 further comprises generating the nanotube suspension by functionalizing nanotubes with molecules of either an acid or an amino group.

3. The method of claim 2 wherein generating the nanotube suspension further comprises sonicating the nanotubes as part of functionalizing the nanotubes.

4. The method of claim 2 wherein functionalizing comprises attaching molecules of either the acid or the amino group to surfaces of the nanotubes.

5. The method of claim 2 further comprising characterizing the nanotubes for functionalities,
wherein characterizing comprises detecting the attachment of the molecules of either the acid or the amino group on the surfaces of the nanotubes.

6. The method of claim 1 wherein the suspension is a nanofiber suspension,
wherein the combining comprises mixing a nanofiber suspension with the nanoparticle-impregnated polymer, and
wherein the method further comprises:
functionalizing nanofibers with molecules of either an acid or an amino group; and
characterizing the nanofibers for functionalities.

7. The method of claim 2 wherein the nanoparticle-impregnated polymer includes nanoparticles having a diameter of approximately less than 100 nanometers, the nanoparticles comprising an oxide powder.

8. The method of claim 7 further comprising treating the nanoparticles with silane prior to mixing the nanoparticles with an epoxy.

9. The method of claim 7 wherein the nanotubes comprise electrically insulating nanotubes to provide an electrically insulating polymer nanocomposite substrate core.

10. The method of claim 7 wherein the nanotubes comprise electrically conductive nanotubes to provide an electrically conductive nanocomposite substrate core.

11. The method of claim 2 wherein the combining the nanotube suspension with the nanoparticle-impregnated polymer provides a polymer composite, and
wherein the method further comprises curing the polymer composite in a mold having substantially cylindrical protrusions therein to form vias in the nanocomposite substrate core.

12. The method of claim 2 further comprising generating the nanoparticle-impregnated polymer by combining either an epoxy resin or a thermoplastic polymer with an oxide powder of nanoparticles having a diameter of approximately less than 100 nanometers.

13. The method of claim 12 wherein the combining the nanotube suspension with the nanoparticle-impregnated polymer comprises melt-mixing.

14. The method of claim 12 wherein the combining the nanotube suspension with the nanoparticle-impregnated polymer comprises solvent-mixing,
wherein the nanotube suspension is mixed with a selected solvent; and
wherein generating the nanoparticle-impregnated polymer comprises mixing an uncured epoxy, epoxy resin, or a thermoplastic polymer with the selected solvent.

15. A method comprising:
functionalizing nanotubes with either an acid or amino group to generate a nanotube suspension;
impregnating a polymer with nanoparticles to generate a nanoparticle-impregnated polymer;
combining the nanotube suspension with the nanoparticle-impregnated polymer to generate a polymer nanocomposite; and
curing the polymer nanocomposite in a mold.

16. The method of claim 15 further comprising treating the nanoparticles with silane prior to impregnating the polymer with the nanoparticles, and
wherein the polymer comprises either an epoxy resin or a thermoplastic.

17. The method of claim 16 wherein generating the nanotube suspension further comprises sonicating the nanotubes as part of functionalizing the nanotubes, and
wherein functionalizing comprises attaching molecules of either the acid or the amino group to surfaces of the nanotubes.

18. The method of claim 17 further comprising characterizing the nanotubes for functionalities by detecting the attachment of the molecules to the surfaces of the nanotubes.

19. The method of claim 17 wherein curing includes curing the polymer nanocomposite in a mold having substantially cylindrical protrusions therein to form vias of a substrate core.

20. The method of claim 17 wherein the combining the nanotube suspension with the nanoparticle-impregnated polymer comprises melt-mixing.

21. The method of claim 17 wherein the combining the nanotube suspension with the nanoparticle-impregnated polymer comprises solvent-mixing,
wherein the nanotube suspension is mixed with a selected solvent; and
wherein generating the nanoparticle-impregnated polymer comprises mixing an uncured epoxy, epoxy resin, or a thermoplastic polymer with the selected solvent.

22. A multi-layer substrate comprising one or more polymer nanocomposite core layers sandwiched between a plurality of laminate layers, wherein each of the polymer nanocomposite core layers comprises a polymer composite of nanoparticles and substantially randomly oriented nanotubes.

23. The substrate of claim 22 wherein the nanoparticles have a diameter of approximately less than 100 nanometers and comprise an oxide powder of either fractured alumina or fractured silica.

24. The substrate of claim 23 wherein the one or more polymer nanocomposite core layers comprises a plurality of vias formed by a mold during curing of the polymer nanocomposite, the vias for use as plated through holes.

25. The substrate of claim 24 wherein the nanotubes comprise electrically insulating nanotubes, and
wherein the one or more polymer nanocomposite core layers are electrically insulating.

26. The method of claim 24 wherein the nanotubes comprise electrically conductive nanotubes, and
wherein the one or more polymer nanocomposite core layers are electrically conductive.

27. A system comprising:
a semiconductor die; and
multi-layer substrate coupled with the semiconductor die, the multi-layer substrate comprising one or more non-conductive core layers sandwiched between a plurality of laminate layers, wherein each of the non-conductive core layers comprises a polymer composite of nanoparticles and substantially randomly oriented nanotubes.

28. The system of claim 27 wherein the nanoparticles have a diameter of approximately less than 100 nanometers and comprise an oxide powder of either fractured alumina or fractured silica.

29. The system of claim 28 wherein the one or more polymer nanocomposite core layers comprises a plurality of vias formed by a mold during curing of the polymer nanocomposite, the vias for use as plated through holes.

30. The system of claim 29 wherein the nanotubes comprise boron nitride nanotubes.
